(19) United States
(12) Patent Application Publication
(10) Pub. No.: US 2016/0247719 A1
(43) Pub. Date: Aug. 25, 2016

(54) Semiconductor Devices And Fabrication Methods With Improved Word Line Resistance and Reduced Salicide Bridge Formation

(71) Applicant: Macronix International Co., Ltd., Hsinchu (TW)

(72) Inventors: Kuan-Chih Chen, New Taipei City (TW); Cheng-Wei Lin, Taipei City (TW); Kuang-Wen Liu, Hsinchu County (TW)

(21) Appl. No.: 15/146,187

(22) Filed: May 4, 2016

Related U.S. Application Data
(62) Division of application No. 14/334,325, filed on Jul. 17, 2014.

(51) Int. Cl. H01L 21/768; H01L 23/528; H01L 29/66; H01L 23/522; H01L 29/792; H01L 21/28; H01L 23/532

(52) U.S. Cl. CPC H01L 21/76889; H01L 21/76816; H01L 21/76877; H01L 21/28282; H01L 23/5283; H01L 23/53266; H01L 23/5226; H01L 29/792; H01L 29/66833

(57) ABSTRACT

Provided are improved semiconductor memory devices and method for manufacturing such semiconductor memory devices. A method may incorporate the formation of silicide regions in a semiconductor. The method may allow for a semiconductor with a silicide layer with improved resistance and reduced silicide bridge formation.

### TECHNOLOGICAL FIELD OF THE INVENTION

The present invention generally relates to semiconductor devices and methods of forming semiconductor devices. In particular, the present invention relates to semiconductor memory devices with silicide layers and methods of forming such semiconductor memory devices. The methods of the invention allow for improved resistance in the semiconductor memory devices and reduced silicide bridge formation in the semiconductor memory devices.

### BACKGROUND

A memory device generally includes an array of memory cells arranged in rows and columns. Each memory cell includes a transistor structure having a gate, a drain, a source, and a channel defined between the drain and the source. The gate corresponds to a word line, and the drain or source correspond to bit lines of the memory array. The gate of a conventional flash memory cell is generally a dual-gate structure, including a control gate and a floating gate, wherein the floating gate is sandwiched between two dielectric layers to trap carriers such as electrons, to program the cell. In SONOS devices, an oxide-nitride-oxide layer is formed between conductive material, such as polysilicon. The nitride layer acts as a charge trapping layer.

To improve the resistance of the gate, a salicide, or self-aligned silicide, layer may be applied in the formation of the gate structure. For example, a cobalt containing silicide layer formed on a transistor or gate that has been isolated from other gates using word line spaces may serve to reduce the resistance of the gate electrode.

The semiconductor industry is increasingly driven towards smaller and more capable electronic devices, such as computing devices, communication devices, and memory devices. In order to reduce the size of such devices, while maintaining or improving their respective capabilities, the size of components within the devices must be reduced. However, issues arise with such reduction.

Applicant has identified deficiencies and problems associated with conventional processes for manufacturing memory devices and the resulting memory devices. For instance, when reducing the transistor width or reducing the isolation distance between word lines with silicide, voids may form between the silicide and conductive material increasing the resistance of the word line. In addition, as the isolation distance is reduced silicide bridges may form between word lines. Through applied effort, ingenuity, and innovation, certain of these identified problems have been solved by developing solutions that are included in various embodiments of the present invention, which are described in detail below.

### BRIEF SUMMARY OF THE INVENTION

Embodiments of the present invention therefore provide methods of manufacturing semiconductor devices with improved resistance and reduced silicide bridge formation, and provide semiconductor devices produced from such methods.

The present invention provides a method of forming a semiconductor with a silicide layer with improved resistance and reduced silicide bridge formation. For instance, in the embodiment of FIG. 2, silicide bridges between the word lines, comprising the silicide region 420, the first conductive layer 370, and the second conductive layer 380, are prevented from forming. Further, in the embodiment of FIG. 2, voids between the silicide region 420 and the second conductive layer 380 are minimized. Without intending to be bound by theory, the method comprises exposing a portion of the active region of the semiconductor prior to formation of the silicide region such that voids between the active region (e.g., the second conductive layer 380 of FIG. 2) and the silicide layer are reduced and the formation of silicide bridges between word lines is reduced.

An aspect of the invention provides a semiconductor device comprising a substrate; an active region located along the substrate; and a silicide layer formed on the active region such that the active region and silicide layer form a word line, wherein a portion of the silicide layer is exposed to form an area between the word line and an adjacent word line.

In certain embodiments of the invention, the semiconductor device may have an area between adjacent word lines with an aspect ratio of 0.1 to 5.0. In some embodiments of the invention, the semiconductor device may have an area between adjacent word lines with an aspect ratio of 0.48 to 4.15.

In an embodiment of the invention, the silicide layer may comprise at least one of cobalt, titanium, nickel, platinum, and tungsten. In one embodiment of the invention, the active region may comprise polysilicon.

An aspect of the invention also provides a method of forming a silicide region in a semiconductor comprising providing a substrate, an active region, and a dielectric region, wherein the active region and dielectric region are formed along the substrate; removing at least a portion of the dielectric region; applying a transition metal along the active region and dielectric region; forming a silicide layer in the active region; and removing excess transition metal along the dielectric region.

In certain embodiments of the invention, removing excess transition metal along the dielectric region forms an area adjacent to the active region with an aspect ratio of 0.1 to 5.0. In certain other embodiments of the invention, removing excess transition metal along the dielectric region forms an area adjacent to the active region with an aspect ratio of 0.48 to 4.15.

In one embodiment of the invention, applying a transition metal along the active region may comprise applying at least one of cobalt, titanium, nickel, platinum, and tungsten. In certain embodiments of the invention, providing an active region may comprise providing polysilicon.

In an embodiment of the invention, the method of forming a silicide region in a semiconductor may further comprise doping the dielectric region with ions. In one embodiment of the invention, removing at least a portion of the dielectric region may comprise etching at least a portion of the dielectric region. In some embodiments, removing excess transition metal along the dielectric region may comprise etching excess transition metal along the dielectric region. In certain embodiments, forming a silicide layer in the active region may comprise heating the semiconductor.

An aspect of the invention also provides a semiconductor device comprising a substrate; a first dielectric layer disposed along the substrate; an active region located adjacent to the first dielectric layer; a dielectric fill material located adjacent to the active region; and a silicide layer formed on the active region, wherein the active region and silicide layer form a word line and wherein a portion of the silicide layer is exposed to form an area between the word line and an adjacent word line. In one embodiment of the invention, the semiconductor device may comprise an area between adjacent word lines with an aspect ratio of 0.1 to 5.0. In other embodiments of the invention, the semiconductor device may comprise an area between adjacent word lines with an aspect ratio of 0.48 to 4.15.

In an embodiment of the invention, the silicide layer may comprise at least one or more of cobalt, titanium, nickel, platinum, and tungsten. In certain embodiments of the invention, the active region may comprise polysilicon. In some embodiments, the first dielectric layer may comprise an oxide-nitride-oxide layer. For instance, in some embodiments, the first dielectric layer may comprise an oxide-nitride-oxide (ONO) layer as part of a SONOS device.

These embodiments of the present invention and other aspects and embodiments of the present invention are described further herein and will become apparent upon review of the following description taken in conjunction with the accompanying drawings.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates the prior art process of silicide formation on a semiconductor;

FIG. 2 illustrates a method of forming silicide according to an embodiment of the invention;

FIG. 3 is a table illustrating the bridge rate formation according to an embodiment of the invention;

FIG. 4 is a table illustrating the resistance according to an embodiment of the invention;

FIG. 5 is an off-line profile of a semiconductor with a shallow etch along a second conductive layer;

FIG. 6 is an off-line profile of a semiconductor with a deep etch along a second conductive layer; and

FIG. 7 shows a process flow chart for a method of forming a semiconductor device according to an embodiment of the invention.

### DETAILED DESCRIPTION OF THE INVENTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

As used in the specification and in the appended claims, the singular forms “a”, “an”, and “the” include plural referents unless the context clearly indicates otherwise. For example, reference to “a semiconductor device” includes a plurality of such semiconductor devices, unless the context clearly indicates otherwise.

As used herein, a “substrate” may include any underlying material or materials upon which a device, a circuit, an epitaxial layer, or a semiconductor may be formed. Generally, a substrate may be used to define the layer or layers that underlie a semiconductor device or even forms the base layer of a semiconductor device. Without intending to be limiting, the substrate may include one or any combination of silicon, doped silicon, germanium, silicon germanium, semiconductor compounds, or other semiconductor materials.

Non-volatile memory refers to a semiconductor device which is able to store information even when the supply of electricity is removed from the memory. Non-volatile memory includes, without limitation, Mask Read-Only Memory, Programmable Read-Only Memory, Erasable Programmable Read-Only Memory, Electrically Erasable Programmable Read-Only Memory, and Flash Memory.

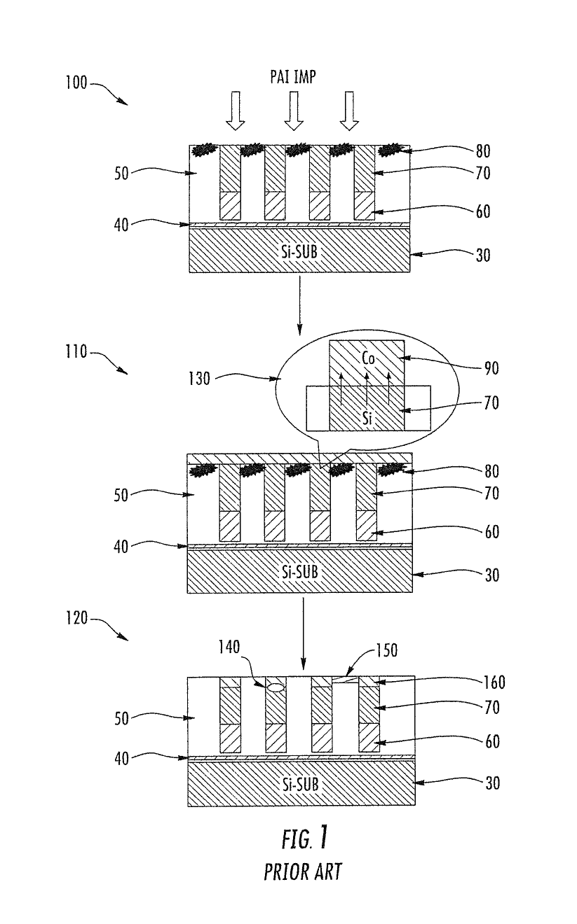

FIG. 1 illustrates the prior art process of silicide formation on a semiconductor. In the process of FIG. 1, the semiconductor comprises a substrate 30 (“Si-Sub”), a first dielectric layer 40, a first conductive layer 60, a second conductive layer 70, and dielectric fill material 50. In the process depicted in FIG. 1, the semiconductor is subjected to pre-amorphous implantation 100 (“PAI IMP”) followed by application of a transition metal, such as cobalt, 110 and removal of excess transition metal 120. As shown in FIG. 1, pre-amorphous implantation 100 results in damaged oxide 80 forming in the dielectric fill material 50. The transition metal 90 is applied over the semiconductor covering the damaged oxide 80. An enlarged area 130 illustrates the formation of the silicide region 160 from the reaction of the transition metal 90 and the second conductive layer 70. Excess transition metal 90 is then removed 120. As illustrated in FIG. 1, the resulting semiconductor contains a void 140 and a silicide bridge 150. The void 140 increases the resistance between the second conductive layer 70 and the silicide area 160. The damaged oxide region 80 is a non-dense dielectric region, which easily forms silicide and causes a silicide bridge to form over the dielectric region between the adjacent word lines.

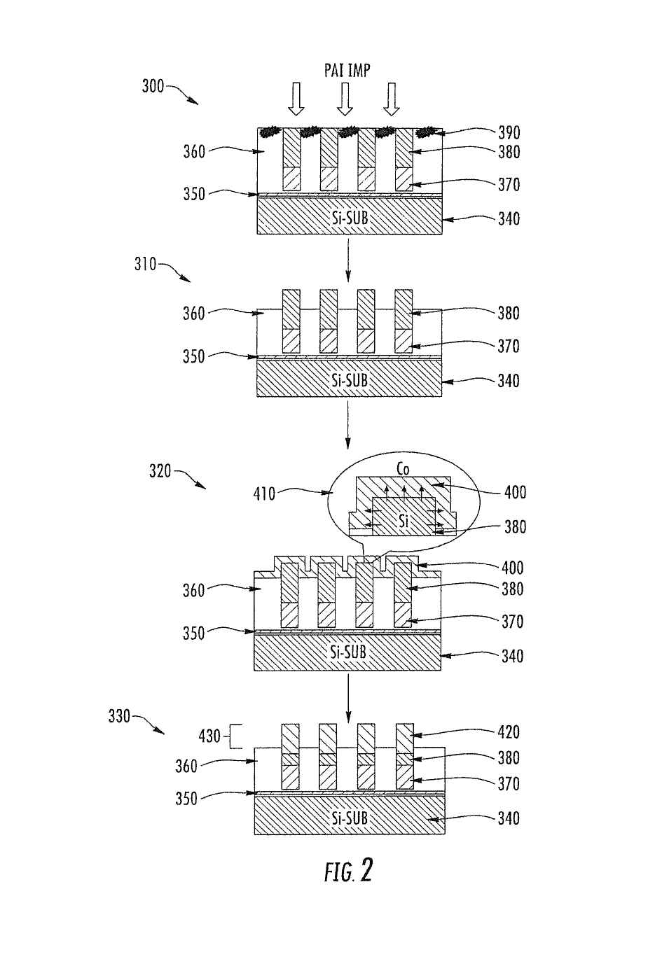

The inventors of the present invention have found a method of manufacturing semiconductors that reduces the occurrence of voids, leading to decreased resistance, and reduces the occurrence of silicide bridges between word lines. FIG. 2 illustrates a method of forming silicide according to an embodiment of the invention. As shown in FIG. 2, the semiconductor comprises a substrate 340 (“Si-Sub”), a first dielectric layer 350, a first conductive layer 370, a second conductive layer 380, and dielectric fill material 360. In the embodiment depicted in FIG. 2, the semiconductor is subjected to doping or pre-amorphous implantation 300 (“PAI IMP”) with ions, removal of at least a portion of the dielectric fill material 310, application of the transition metal 320, and removal of excess transition metal along the dielectric region 330.

To form the semiconductor illustrated in FIG. 2, a first dielectric layer 350 is formed on a substrate 340. The first dielectric layer 350 may comprise any suitable dielectric material, such as silicon oxide (SiO₂), silicon nitride (Si₃N₄), silicon oxynitride (SiOₓN_{y}), or any combination thereof. In certain embodiments, the first dielectric layer may comprise an oxide-nitride-oxide (ONO) layer. For instance, in some embodiments, the first dielectric layer may comprise an oxide-nitride-oxide (ONO) layer as part of a SONOS device. The first dielectric layer 350 may be formed by any suitable deposition process, such as chemical vapor deposition (CVD) or spin-on dielectric processing. In certain embodiments, the first dielectric layer 350 may be grown on the substrate 340.

In the embodiment of FIG. 2, a first conductive layer 370 is formed over the first dielectric layer 350. In some embodiments, the first conductive layer 370 may comprise polysilicon. The first conductive layer may be formed by any suitable process, such as CVD or spin coating.

In the embodiment of FIG. 2, a second conductive layer 380 is then formed over the first conductive layer 370. In some embodiments, the second conductive layer 380 may comprise polysilicon. The second conductive layer may be formed by any suitable process, such as CVD or spin coating.

In some embodiments, a second dielectric layer may be formed between the first conductive layer and the second conductive layer. The second dielectric layer may be any suitable dielectric layer, such as silicon oxide (SiO₂), silicon oxynitride (SiOₓN_{y}), silicon nitride (Si₃N₄), or any combination thereof. In certain embodiments, the dielectric layer may be an oxide-nitride-oxide (ONO) layer. The dielectric layer may be formed by any suitable deposition process, such as CVD or spin-on dielectric processing.

Further, to form the semiconductor depicted in FIG. 2, at least a portion of the first conductive layer 370 and the second conductive layer 380 are removed to form word lines. In some embodiments, etching may be performed to remove at least a portion of the first conductive layer 370 and the second conductive layer 380 to form spaces between word lines. The etching may be wet or dry etching. Non-limiting examples of wet etch processes include chemical vapor etching, metal assisted etching, and electroless etching. For example, chemical vapor etching may be performed using an acidic etching solution, such as mixtures comprising HNO₃ and/or HF. In certain embodiments, the wet etch process may be a buffered oxide etch process or a buffered hydrofluoric acid process. Non-limiting examples of dry etching processes include plasma etching, sputter etching, ionization etching, and reactive ion etching. In certain embodiments, at least a portion of the first conductive layer and the second conductive layer are removed in one step, while in other embodiments, at least a portion of the first conductive layer and the second conductive layer are removed in several steps utilizing one or more removal processes. In certain embodiments, a portion of the first conductive layer may be removed to form a floating gate and a portion of the second conductive layer may be removed to form a control gate.

To form the semiconductor depicted in FIG. 2, dielectric fill material 360 is then applied to the semiconductor. In the embodiment depicted in FIG. 2, the dielectric fill material 360 fills the spaces between the word lines comprising the first conductive layer 370 and the second conductive layer 380. The dielectric fill material 360 may be any suitable dielectric material, such as silicon oxide (SiO₂), a silicon oxynitride (SiOₓN_{y}), or any combination thereof. The dielectric fill material 360 may be formed by any suitable deposition process, such as chemical vapor deposition (CVD) or spin-on dielectric processing.

In certain embodiments of the invention, excess dielectric fill material may be removed along the semiconductor. Excess dielectric fill material may be removed by any suitable removal process, such as etching, chemical-mechanical polishing, or any combination thereof. In some embodiments of the invention, excess dielectric fill material may be removed to planarize the semiconductor.

In the embodiment of FIG. 2, ions are implanted in the dielectric fill material. Doping the dielectric fill material with ions may lower the dielectric constant improving the resistance of the material and the isolation of the word lines surrounding the dielectric fill material. However, as illustrated in FIG. 2, during pre-amorphous implantation 300, damaged oxide 390 may form on the exposed portion of the dielectric fill material 360. Without intending to be bound by theory, the implanted ions collide with the atoms of the dielectric fill material 360 dislodging some of the atoms and damaging the structure of the dielectric fill material 360. Thus, a damaged oxide region 390 may be formed in the dielectric fill material 360.

In the embodiment of FIG. 2, a layer of the dielectric fill material 360 is removed leaving an exposed portion of the second conductive layer 380. In some embodiments, dielectric fill material 360 may be removed by etching the material. In certain embodiments of the invention, the damaged oxide region 390 may be removed along with a portion of the dielectric fill material 360. Any etching process may be used, such as wet or dry etching. In certain embodiments, dielectric fill material may be selectively etched by an etchant with a preference for the dielectric fill material. Preferably, the selective etch provides an exposed region of the second conductive layer 380 as shown in process step 310 of FIG. 2. Without intending to be bound by theory, the inventors have found that etching the damaged oxide region 390 and/or the dielectric fill material 360 to remove the damaged oxide region 390 reduces the occurrence of silicide bridge formation.

In some embodiments, the damaged oxide and/or dielectric fill material may be etched to expose a portion of the second conductive layer such that the ratio of the width of the distance between adjacent word lines and the depth of the etch (i.e., the aspect ratio) is less than 5.0. In other embodiments, the aspect ratio may be about 0.1 to about 5.0. In yet a further embodiment, the aspect ratio may be about 0.48 to about 4.15.

The inventors have found exposing a portion of the second conductive layer such that the aspect ratio of the area between word lines may be less than about 5.0, preferably about 0.1 to about 5.0, and more preferably about 0.48 to about 4.15, improves the resistance of word lines and reduces the occurrence of silicide bridges between word lines.

In some embodiments of the invention, a silicide layer is preferably formed in the semiconductor device. A silicide layer may improve the resistance of an active region. In certain embodiments, a transition metal may be applied to an active region to form a silicide layer. The active region preferably comprises conductive material, such as polysilicon. Without intending to be bound by theory, the transition metal reacts with the silicon of the active region to form silicide. In certain embodiments, such as the one depicted in FIG. 2, the active region comprises a second conductive layer 380.

To form a silicide layer in the embodiment of FIG. 2, a transition metal 400 is applied over the semiconductor. Any suitable metal may be used, such as cobalt, titanium, nickel, platinum, tungsten, or any combination thereof. In the embodiment of FIG. 2, the transition metal 400 comprises cobalt.

A transition metal may be applied by any suitable deposition method, such as chemical vapor deposition, electroplating, evaporation, sputtering, or other coating methods.

In some embodiments, the thickness of the transition metal may be increased to improve the resistance of the word line. In such embodiments, the amount of silicon available should be sufficient to react with the metal and avoid the formation of a silicide void in the word line.

In the embodiment of FIG. 2, the transition metal 400 covers the exposed portion of a second conductive layer 380. FIG. 2 includes an enlarged section 410 of one area of the second conductive layer 380 and the layer of transition metal 400 applied over the second conductive layer 380.

After application of the transition metal, the semiconductor may undergo a heating step to expose the transition metal to an elevated temperature for some amount of time. Without intending to be bound by theory, the application of heat causes the transition metal to react with the active region. In certain embodiments, the active region comprises silicon. For instance, in FIG. 2, the active region comprises a second conductive layer 380 which comprises silicon. The enlarged section 410 illustrates the interaction between the silicon of the second conductive layer 380 and the transition metal 400 for this embodiment. The silicon of the second conductive layer 380 and the transition metal 400 react to form silicide 420. In the embodiment depicted in FIG. 2, the application of heat causes the transition metal (i.e., cobalt in the embodiment of FIG. 2) to react with silicon of the second conductive layer 380 to form CoSi and Co₂Si. Depending on the heating conditions, CoSi₂ may also be formed. CoSi₂ possesses the lowest resistance of the combinations and is preferred in a finished silicide layer.

Following this heating step, unreacted transition metal may be removed leaving behind a layer of reacted material. For instance, in the embodiment of FIG. 2, the transition metal 400 prefers to react with silicon in the second conductive layer 380 rather than the dielectric fill material 360. Thus, unreacted metal, or excess metal, may remain on the dielectric fill material 360. The unreacted metal or excess metal may be removed by any suitable removal process, such as etching or chemical mechanical polishing. For instance, in some embodiments, the semiconductor may be subjected to dry or wet etching to remove excess transition metal. The wet etch process may be a hydrofluoric acid (HF) etching process, an etching process using a buffered oxide etchant (BOE), or an etching process using a buffered hydrofluoric acid (BHF). In certain embodiments of the invention, the semiconductor may be subjected to a selective etch to remove excess transition metal.

In certain embodiments of the invention, excess transition metal 400 may be removed to provide an exposed portion 430 of the silicide layer 420 in the semiconductor. For instance, as shown in process step 330 of FIG. 2, excess transition metal 400 is removed to provide an exposed portion 430 of the silicide layer 420.

In some embodiments, excess transition metal may be removed such that the ratio of the width of the distance between word lines and the depth of the etch (i.e., the aspect ratio) is less than 5.0. In other embodiments, the excess transition metal may be removed such that the aspect ratio may be about 0.1 to about 5.0. In yet a further embodiment, excess transition metal may be removed such that the aspect ratio may be from about 0.48 to about 4.15.

In certain embodiments of the invention, the excess metal may be removed along with a portion of the dielectric fill material. The excess metal and dielectric fill material may be removed in one removal step or a series of removal steps comprising etching, chemical mechanical polishing, or any combination thereof. The excess metal and dielectric fill material may be etched by dry or wet etching. In certain embodiments, the wet etch process may be a hydrofluoric acid (HF) etching process, an etching process using a buffered oxide etchant (BOE), or an etching process using a buffered hydrofluoric acid (BHF).

In certain embodiments of the invention, the semiconductor may be subjected to an additional heating step. In certain embodiments of the invention, the silicide region 420 may be formed using a plurality of heating steps, prior to and/or after removal of excess transition metal. Without intending to be bound by theory, the additional heating step may convert the silicide to a material of lower resistance. For instance, in the embodiment of FIG. 2, an additional heating step may convert CoSi and Co₂Si to CoSi₂, thus, imparting lower resistance to the silicide layer.

One exemplary method for forming a silicide region 420 has been described herein. But any method known in the art for forming the silicide region 420 may be used without departing from the invention.

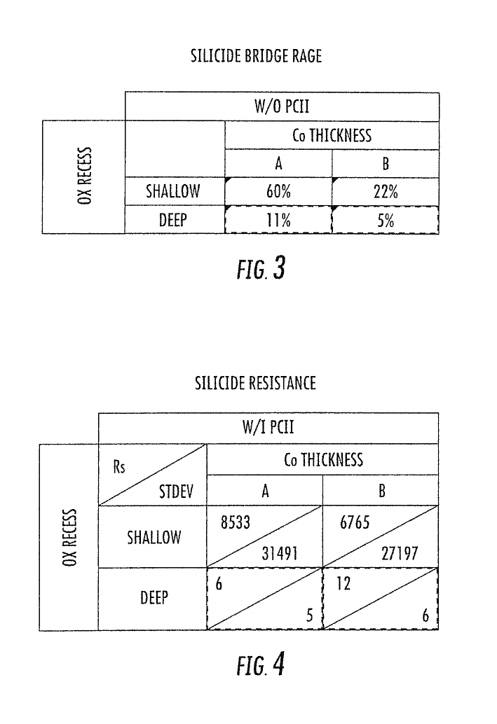

FIG. 3 is a table illustrating the rate of bridge formation according to an embodiment of the invention. In FIG. 3, the rate of silicide bridge formation is compared between thin and thick layers of cobalt and compared between shallow and deep etching along the second conductive layer.

FIG. 4 is a table illustrating the resistance according to an embodiment of the invention. In FIG. 4, the resistance is compared between thin and thick cobalt layers and compared between shallow and deep etching along the second conductive layer. In both FIG. 3 and FIG. 4, the thickness of cobalt applied to the semiconductors for examples A and B is 60 Å and 50 Å, respectively. The shallow etch is to a depth of 100 Å and the deep etch is to a depth of 500 Å. Both FIGS. 3 and 4 are for illustration only and are not intended to limit the invention.

As shown in FIG. 3, when a deeper etch is made to expose a portion of the second conductive layer, the rate of silicide bridge formation is significantly reduced as compared to a shallower etch along the second conductive layer.

As shown in FIG. 4, when a deeper etch is made to expose a portion of the second conductive layer, the resistance is significantly reduced between word lines as compared to a shallower etch along the second conductive layer. FIGS. 3 and 4 additionally show that the use of a thinner layer of cobalt may provide reduced bridge formation but with slightly increased resistance as compared to a thicker layer of cobalt.

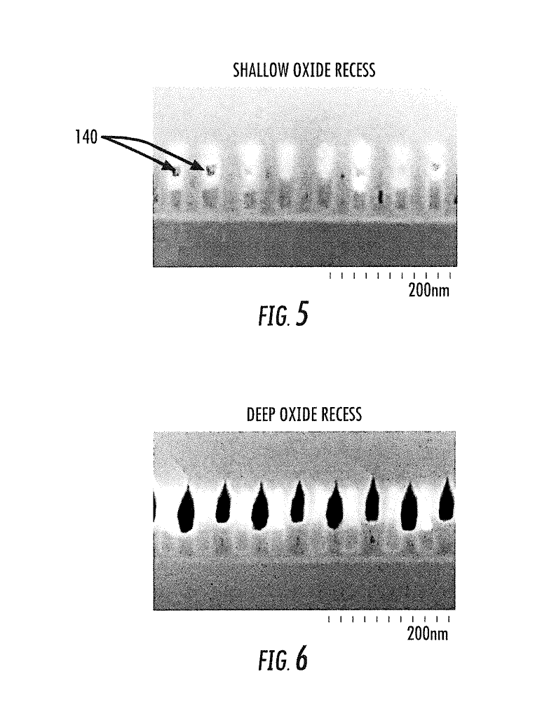

FIG. 5 is an off-line profile of a shallow etch along the second conductive layer. The image illustrates voids 140 between the silicide and the second conductive layer. In FIG. 5, the etch is to a depth of 100 Å. FIG. 6 is an off-line profile of a deep oxide recess. FIG. 6 illustrates that the formation of deep oxide recesses provides a semiconductor free of voids between silicide layers and active regions. In FIG. 6, the etch is to a depth of 500 Å.

As shown in FIGS. 3-6, the inventors have found a deeper etch to expose a portion of the second conductive layer such that an area between word lines is formed with an aspect ratio of less than about 5.0, preferably about 0.1 to about 5.0, and more preferably about 0.48 to about 4.15, improves the resistance of word lines as the formation of voids in word lines is reduced.

While the above has been described in terms of etching, a portion of the second conductive layer can be exposed by other methods such as chemical mechanical polishing or combinations thereof.

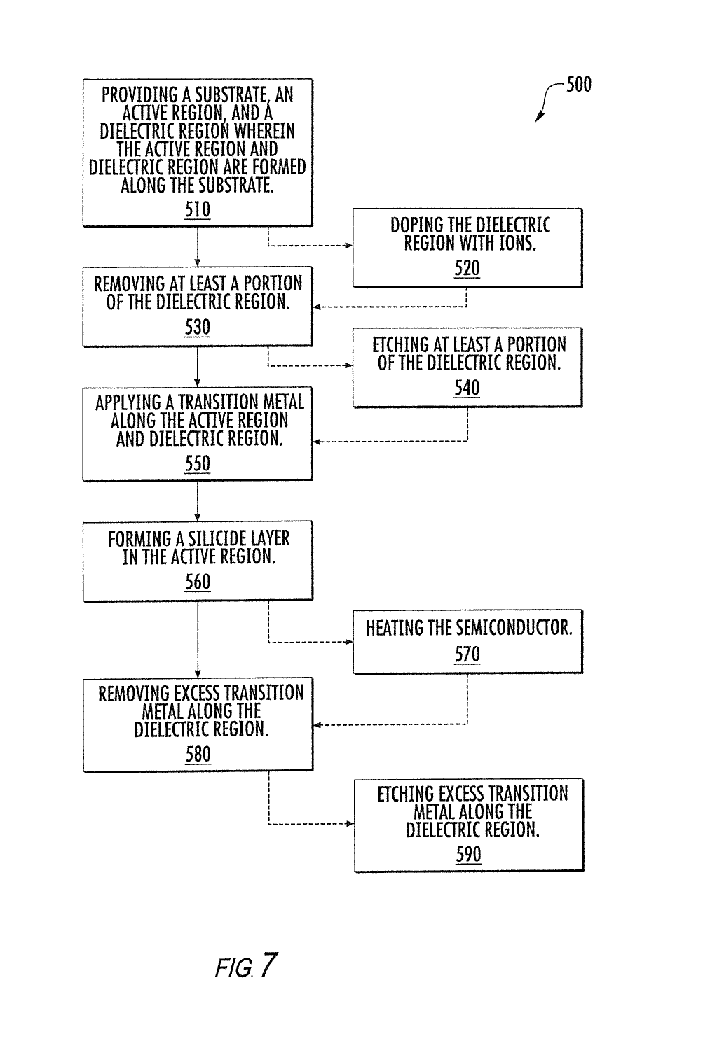

FIG. 7 shows a process flow chart for a method of forming a semiconductor device according to an embodiment of the invention. As shown in FIG. 7, the method comprises providing a substrate, an active region, and a dielectric region 510; removing at least a portion of the dielectric region 530; applying a transition metal along the active region and dielectric region 550; forming a silicide layer in the active region 560; and removing excess transition metal along the dielectric region 580. In certain embodiments of the invention, the method may further comprise doping the dielectric region with ions 520. In one embodiment of the invention, the step of removing at least a portion of the dielectric region may comprise etching at least a portion of the dielectric region 540. In some embodiments of the invention, the step of forming a silicide layer in the active region may comprise heating the semiconductor 570. In certain embodiments of the invention, the removal of excess transition metal along the dielectric region may comprise etching excess transition metal along the dielectric region 590. The method of the present invention may include various combinations of the steps illustrated in FIG. 7.

Certain of the steps generally described above in the method may themselves comprise other sub-steps that have not necessarily been identified. Such additional steps are understood by a person of ordinary skill in the art having the benefit of this disclosure.

An aspect of the invention provides a semiconductor fabricated using the processes or methods for fabricating a semiconductor as disclosed herein. In certain other embodiments of the invention, a semiconductor device may be fabricated using any combination of the method steps as described herein. Further, any manufacturing process known to those having ordinary skill in the art having the benefit of this disclosure may be used to manufacture the semiconductor devices in accordance with embodiments of the present invention.

The present invention may be used for the fabrication of any memory device. For instance, the method of the present invention may be applied to the fabrication of any non-volatile memory device, such as flash memory devices. In certain embodiments, the method of the present invention is used for the fabrication of NOR or NAND devices.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of forming a semiconductor device, the method comprising:
forming a first conductive line and a second conductive line over a substrate;
forming a dielectric fill material physically touching the first conductive line, wherein a ratio of 1) a distance between the first conductive line and the second conductive line to 2) a difference in height of the first conductive line and the dielectric fill material is from about 0.1 to about 5.0; and
converting at least a portion of the first conductive line into one or more silicide regions.

2. The method of claim 1, wherein a ratio of 1) a distance between the first conductive line and the second conductive line to 2) a difference in height of the first conductive line and the dielectric fill material is from about 0.48 to about 4.15.

3. The method of claim 1, wherein converting at least a portion of the first conductive line into one or more silicide regions comprises applying at least one of cobalt, titanium, nickel, platinum, and tungsten to the first conductive line.

4. The method of claim 1, wherein the first conductive line and second conductive line comprise polysilicon.

5. The method of claim 1, further comprising doping the dielectric fill material with ions.

6. The method of claim 1, wherein converting at least a portion of the first conductive line into one or more silicide regions comprises heating the semiconductor.

7. The method of claim 1, wherein converting at least a portion of the first conductive line into one or more silicide regions comprises forming CoSi₂.

8. A method of forming a semiconductor device, the method comprising:
forming a first word line and a second word line;
forming a dielectric fill material physically touching the first word line;
etching the dielectric fill material to provide a ratio of 1) a distance between the first word line and the second word line to 2) a difference in height of the first word line and the dielectric fill material is from about 0.1 to about 5.0; and
converting at least a portion of the first word line into one or more silicide regions.

9. The method of claim 8, wherein a ratio of 1) a distance between the first word line and the second word line to 2) a difference in height of the first conductive line and the dielectric fill material is from about 0.48 to about 4.15.

10. The method of claim 8, wherein converting at least a portion of the first word line into one or more silicide regions comprises applying at least one of cobalt, titanium, nickel, platinum, and tungsten.

11. The method of claim 8, wherein the first word line comprises a first conductive layer and a second conductive layer.

12. The method of claim 8, further comprising doping the dielectric fill material with ions.

13. The method of claim 8, wherein converting at least a portion of the first word line into one or more silicide regions comprises forming CoSi₂.

14. A method of forming a semiconductor device, the method comprising:
forming a first word line comprising a first conductive layer and a second conductive layer;
forming a dielectric fill material physically touching at least one of the first conductive layer and the second conductive layer, wherein a ratio of 1) a distance between the first word line and a second word line to 2) a difference in height of the first word line and the dielectric fill material is from about 0.1 to about 5.0; and
converting at least a portion of the second conductive layer into one or more silicide regions.

15. The method of claim 14, further comprising doping the dielectric fill material with ions.

16. The method of claim 14, wherein converting at least a portion of the second conductive layer into one or more silicide regions comprises forming CoSi₂.

17. The method of claim 14, wherein further comprising forming an oxide-nitride-oxide layer prior to forming the first word line.

18. The method of claim 14, wherein a ratio of 1) a distance between the first word line and the second word line to 2) a difference in height of the first word line and the dielectric fill material is from about 0.48 to about 4.15.

19. The method of claim 14, wherein converting at least a portion of the second conductive layer into one or more silicide regions comprises applying at least one of cobalt, titanium, nickel, platinum, and tungsten.

20. The method of claim 14, wherein forming the second word line comprises providing polysilicon.
